(19) United States
(12) Patent Application Publication
(10) Pub. No.: US 2024/0238939 A1
(43) Pub. Date: Jul. 18, 2024

(54) SUBSTRATE POLISHING APPARATUS

(71) Applicant: SAMSUNG ELECTRONICS CO., LTD., SUWON-SI (KR)

(72) Inventors: Jihyeon Kim, Suwon-si (KR); Donghoon Kwon, Suwon-si (KR)

(21) Appl. No.: 18/515,780

(22) Filed: Nov. 21, 2023

(30) Foreign Application Priority Data
Jan. 16, 2023 (KR) 10-2023-0006013

(51) Int. Cl. B24B 57/02; B08B 3/02; B24B 37/015

(52) U.S. Cl. CPC B24B 57/02; B08B 3/02; B24B 37/015

(57) ABSTRACT

A substrate polishing apparatus includes a platen having an upper surface configured to polish a semiconductor substrate, a slurry supply configured to supply slurry between the semiconductor substrate and the platen, a substrate holder configured to hold the semiconductor substrate and to bring the semiconductor substrate in contact with the upper surface of the platen, the substrate holder having a circular shape, a temperature controller configured to control temperature of the platen through thermal transfer via direct contact, wherein the temperature controller has a thermal conductive body that has an arc shape and the thermal conductive body is spaced apart from the substrate holder and surrounds at least a portion of the substrate holder, and a cleaning component configured to supply a cleaning solution to the substrate holder and the temperature controller.

### CROSS-REFERENCE TO RELATED APPLICATION

This application claims priority under 35 U.S.C. § 119 to Korean Patent Application No. 10-2023-0006013, filed on Jan. 16, 2023 in the Korean Intellectual Property Office (KIPO), the disclosure of which is incorporated by reference herein in its entirety.

### BACKGROUND

Embodiments of the present disclosure relate to a substrate polishing apparatus. More particularly, embodiments relate to a substrate polishing apparatus used to perform a polishing process on a semiconductor substrate with a slurry.

### DISCUSSION OF THE RELATED ART

Semiconductor substrate polishing, also referred to as wafer polishing, is a process used in the manufacturing of semiconductors. Polishing processes create a smooth and flat surface on the wafer, contributing to the operational characteristics of the devices that use the wafer. There are a number of methods employed for substrate polishing, including mechanical polishing, electrolytic in-process dressing (ELID), and chemical mechanical polishing (CMP). CMP is a technique that uses a combination of chemical and mechanical processes. During CMP, a wafer is polished with a chemically reactive slurry and a polishing pad, a process that is aimed at both the removal of surface imperfections and the minimization of subsurface damage.

CMP processes may use temperature control to improve polishing performance. The temperature control may include a non-contact method that involves spraying a fluid onto a platen, or include a contact method of transferring heat to the platen via a heat conductor. The non-contact method may cause the temperature control fluid to mix with the slurry, thereby diluting it. The contact method prevents this issue, however, conventional contact methods can result in slurry and pad debris build-up in the heat conductor, causing contamination and solidification.

### SUMMARY

Example embodiments provide a substrate polishing apparatus including a cleaning component capable of preventing contamination and solidification that occurs in a temperature controller.

According to example embodiments, a substrate polishing apparatus includes a platen having a surface configured to perform a polishing process on a semiconductor substrate, a slurry supply configured to supply slurry between the semiconductor substrate and the platen, a substrate holder configured to grip and fix the semiconductor substrate so as to be brought into contact with the platen such that the semiconductor substrate contacts the surface of the platen to be polished, the substrate holder having a circular shape, a temperature controller configured to contact the surface of the platen to control temperature, the temperature controller having a thermal conductive body that has an arc shape, the thermal conductive body spaced apart from the substrate holder and surrounding at least a portion of the substrate holder, and a cleaning component configured to supply a cleaning solution to the substrate holder and the temperature controller.

According to example embodiments, a substrate polishing apparatus includes a platen having a surface configured to perform a polishing process on a semiconductor substrate, a slurry supply configured to supply slurry between the semiconductor substrate and the platen, a substrate holder configured to grip and fix the semiconductor substrate so as to be brought into contact with the platen such that the semiconductor substrate contacts the surface of the platen to be polished, the substrate holder having a circular shape, a temperature controller configured to contact the surface of the platen to control temperature, the temperature controller having a thermal conductive body that has an arc shape, the thermal conductive body spaced apart from the substrate holder and surrounding at least a portion of the substrate holder, the thermal conductive body having a plurality of grooves on a lower surface, the temperature controller configured to be movable to have a predetermined distance from the substrate holder, and a cleaning component configured to supply a cleaning solution to the substrate holder and the temperature controller.

According to example embodiments, a substrate polishing apparatus includes a platen having a surface configured to perform a polishing process on a semiconductor substrate, a slurry supply configured to supply slurry between the semiconductor substrate and the platen, a substrate holder configured to grip and fix the semiconductor substrate so as to be brought into contact with the platen such that the semiconductor substrate contacts the surface of the platen to be polished, the substrate holder having a circular shape, a temperature controller configured to contact the surface of the platen to control temperature, a temperature controller configured to be movable to have a predetermined distance from the substrate holder, and a cleaning component configured to supply a cleaning solution to the substrate holder and the temperature controller. The temperature controller includes a thermal conductive body having an arc shape that surrounds at least a portion of the substrate holder and is spaced apart from the substrate holder, the thermal conductive body having a plurality of grooves on a lower surface, a first thermal conductive structure provided on an inner surface of the thermal conductive body, a second thermal conductive structure provided on an outer surface of the thermal conductive body, a first fluid transfer line configured to move cooling water along the lower surface of the thermal conductive body, and a second fluid transfer line configured to heating water along the lower surface of the thermal conductive body.

According to example embodiments, a substrate polishing apparatus may include a platen having a surface configured to perform a polishing process on a semiconductor substrate, a slurry supply configured to supply slurry between the semiconductor substrate and the platen, a substrate holder configured to grip and fix the semiconductor substrate so as to be brought into contact with the platen such that the semiconductor substrate contacts the surface of the platen to be polished, the substrate holder having a circular shape, a temperature controller configured to contact the surface of the platen to control temperature, the temperature controller having a thermal conductive body that has an arc shape, the thermal conductive body spaced apart from the substrate holder and surrounding at least a portion of the substrate holder, and a cleaning component configured to supply a cleaning solution to the substrate holder and the temperature controller.

Thus, the temperature controller of the substrate polishing apparatus may directly contact the platen to control the temperature on the platen. Since the temperature controller is in direct contact with the platen, the substrate polishing apparatus may prevent dilution of the slurry. Since the substrate polishing apparatus does not spray fluid onto the platen, waste water may be reduced.

Since the temperature controller has the arc shape of the thermal conductive body surrounding the circular shape of the substrate holder, temperature in a peripheral area of the substrate holder may be effectively controlled. Since the temperature controller moves in conjunction with the substrate holder on the platen, the temperature may be efficiently controlled. Since the temperature controller and the substrate holder have structures corresponding to each other, the cleaning component may simultaneously clean the temperature controller and the substrate holder.

In some embodiments, the thermal conductive body of the temperature controller includes a plurality of grooves on a lower surface. The thermal conductive body may efficiently distribute the slurry on the platen through the plurality of grooves.

### BRIEF DESCRIPTION OF THE DRAWINGS

Embodiments of the present disclosure will be more clearly understood from the following detailed description taken in conjunction with the accompanying drawings. FIGS. 1 to 12 represent non-limiting embodiments as described herein.

FIG. 1 is a perspective view that illustrates a substrate polishing apparatus in accordance with example embodiments.

FIG. 2 is a plan view that illustrates a substrate polishing apparatus.

FIG. 3 is a front view that illustrates a substrate polishing apparatus.

FIGS. 4 to 7 are views that illustrate a thermal conductive body having a plurality of grooves.

FIG. 8 is a plan view that illustrate a substrate polishing apparatus including a temperature controller that has a thermal conductive structure in accordance with embodiments of the present disclosure.

FIGS. 9 to 11 are views that illustrate a thermal conductive body having a plurality of grooves.

FIG. 12 is a plan view that illustrates a substrate polishing apparatus including a temperature controller that is independently controlled from a substrate holder in accordance with embodiments of the present disclosure.

### DETAILED DESCRIPTION

Embodiments of the present disclosure relate to chemical mechanical polishing (CMP). In a CMP process, temperature control may be used to improve performance of a semiconductor substrate. In some cases, the temperature control may include a non-contact method of spraying a fluid onto a platen, or a contact method of transferring heat to the platen via a heat conductor. In the contact method, since the fluid is not exposed on the platen, a dilution of the slurry by the fluid might not occur. However, the contact method may cause the slurry and pad debris to contact a temperature controller, resulting in possible contamination and solidification.

According to embodiments of the disclosure, a temperature controller of a substrate polishing apparatus may directly contact a platen to control temperature on the platen. Since the temperature controller is in direct contact with the platen, the substrate polishing apparatus may prevent dilution of slurry. Since the substrate polishing apparatus does not spray fluid onto the platen, waste fluid may be reduced.

In some embodiments, the temperature controller has an arc shape of a thermal conductive body surrounding a circular shape of a substrate holder. Accordingly, a temperature in a peripheral area of the substrate holder may be effectively controlled. Since the temperature controller moves in conjunction with the substrate holder on the platen, the temperature may be efficiently controlled.

In some embodiments, the temperature controller and the substrate holder have corresponding structures, such that a cleaner may simultaneously clean the temperature controller and the substrate holder. Furthermore, the thermal conductive body of the temperature controller may have a plurality of grooves on a lower surface. Accordingly, the thermal conductive body may efficiently distribute the slurry on the platen through the plurality of grooves.

Hereinafter, embodiments will be explained in detail with reference to the accompanying drawings.

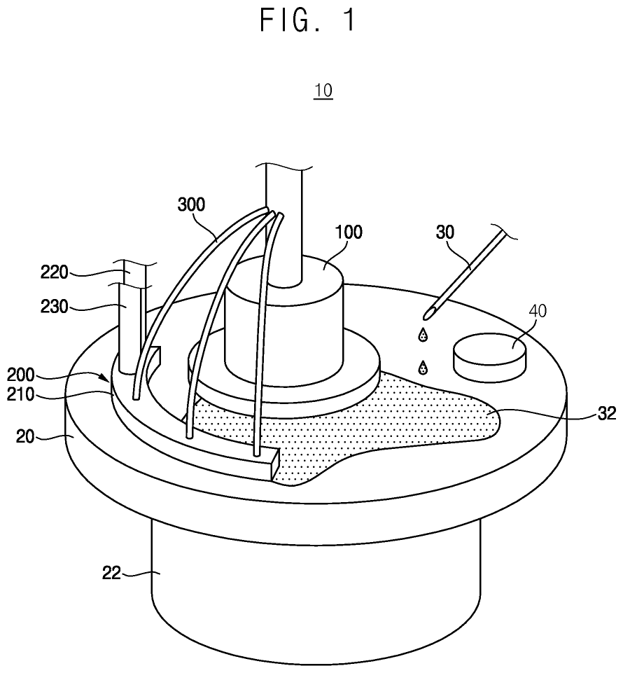

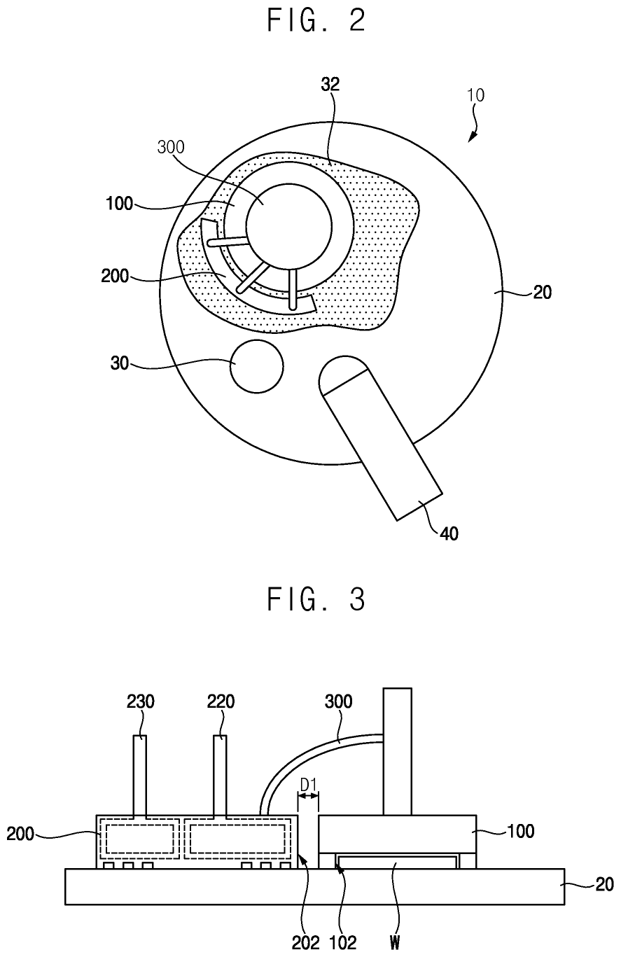

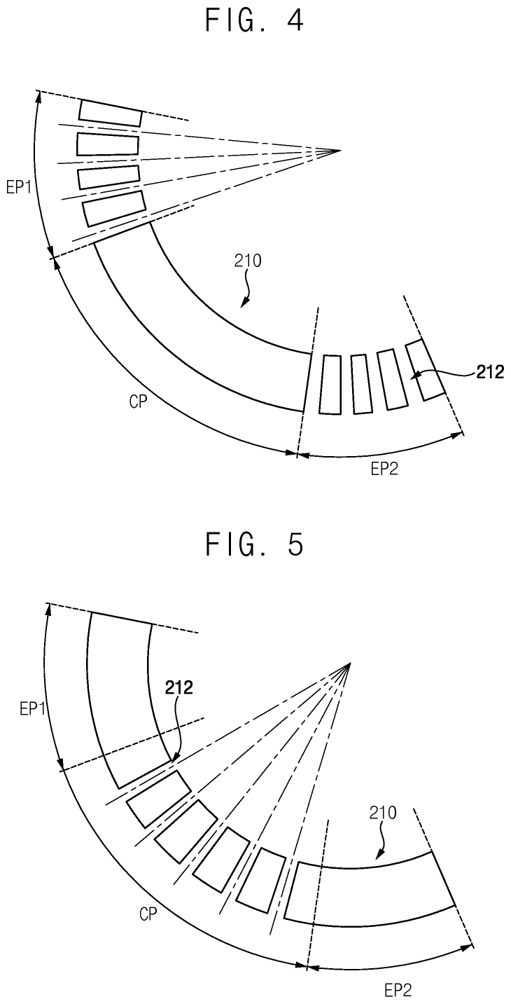

FIG. 1 is a perspective view that illustrates a substrate polishing apparatus in accordance with embodiments of the present disclosure. FIG. 2 is a plan view that illustrates a substrate polishing apparatus in accordance with embodiments of the present disclosure. FIG. 3 is a front view that illustrates a substrate polishing apparatus in accordance with embodiments of the present disclosure. FIGS. 4 to 7 are views that illustrate a thermal conductive body having a plurality of grooves in accordance with embodiments of the present disclosure.

Referring to FIGS. 1 to 7, a substrate polishing apparatus 10 may include a platen 20 configured to support a semiconductor substrate W, a slurry supply 30 configured to supply slurry 32 between the semiconductor substrate W and the platen 20, a substrate holder 100 configured to hold the semiconductor substrate W on the platen 20 in a fixed position and to enable the semiconductor substrate W to be attached or detached from the platen 20, a temperature controller 200 configured to control temperature of the platen 20, and a cleaning component 300 configured to simultaneously clean the substrate holder 100 and the temperature controller 200.

Embodiments of the substrate polishing apparatus 10 are capable of partially removing a portion of a surface of the semiconductor substrate W by a grinding process such as a chemical mechanical polishing (CMP) process. The substrate polishing apparatus 10 may polish the semiconductor substrate W to a desired thickness. Examples of the semiconductor substrate W may include a wafer.

In example embodiments, the platen 20 may have a surface configured to perform a polishing process on the one surface of the semiconductor substrate W. For example, an upper surface of platen 20 may face a lower surface of semiconductor substrate W to be polished. Platen 20 may be supported by a shaft 22. The platen 20 may be rotated clockwise or counterclockwise by the shaft 22. In the polishing process, the semiconductor substrate W may be disposed on the upper surface of the platen 20.

In the polishing process, the lower surface of the semiconductor substrate W and the upper surface of the platen 20 may directly contact each other. The platen 20 may have surface roughness and include fine concavo-convex shapes on the upper surface. The surface roughness may be a threshold amount of roughness that can be reduced through a polishing process of the lower surface of the semiconductor substrate W by the substrate polishing apparatus 10.

The shaft 22 may apply rotational force to rotate the platen 20. The platen 20 may evenly apply the slurry 32 on the platen 20 using the rotation. The platen 20 may generate frictional force with the semiconductor substrate W through the rotation and the configuration of the semiconductor substrate W as held by substrate holder 100. The platen 20 may apply frictional force between the semiconductor substrate W and the slurry 32. In some embodiments, the platen 20 includes a material such as glass, quartz, fused silica, or sapphire.

In some embodiments, the slurry supply 30 supplies the slurry 32 onto the platen 20. The slurry supply 30 may supply the slurry 32 between the semiconductor substrate W and the platen 20. The slurry 32 may be uniformly applied on the platen 20 by the rotation of the platen 20. For example, the slurry 32 may be spread evenly by centrifugal effects as a result of the rotation of platen 20.

In example embodiments, the slurry 32 may include an aqueous solution having fluidity and abrasive particles moving in the aqueous solution. For example, the aqueous solution may include an alkaline solution or an acidic solution, or a combination of the two solutions.

The slurry 32 may further include a booster that adheres to a polishing layer of the semiconductor substrate W to increase polishing strength. In some cases, the slurry 32 may further include an inhibitor that adheres to the polishing layer of the semiconductor substrate W to reduce the polishing strength. The booster and the inhibitor may vary depending on a material composition of the polishing layer of the semiconductor substrate W.

In example embodiments, the substrate holder 100 may hold the semiconductor substrate W on the platen 20 such that the semiconductor substrate W can be attached or detached from the platen 20. The substrate holder 100 may fix and transport the semiconductor substrate W, e.g., before or after polishing. The substrate holder 100 may have a circular shape capable of accommodating the semiconductor substrate W.

The substrate holder 100 may move the semiconductor substrate W on the platen 20. The substrate holder 100 may be configured to move horizontally (e.g., in directions parallel to the upper surface the platen 20) and vertically on the platen 20 (e.g., a direction perpendicular to the upper surface of the platen 20). For example, substrate holder 100 may press the semiconductor substrate W in a vertical direction. The substrate holder 100 may press the semiconductor substrate W to increase the frictional force between the semiconductor substrate and the slurry 32. In some examples, the platen 20 and the substrate holder 100 rotate in opposite directions to increase the frictional force.

In example embodiments, the temperature controller 200 may include a thermal conductive body 210 which contacts the platen 20 and is capable of controlling the temperature of the platen 20, a first fluid transfer line 220 capable of absorbing heat from the thermal conductive body 210, and a second fluid transfer line 230 capable of supplying heat to the thermal conductive body 210.

The thermal conductive body 210 may contact the surface of the platen 20 to control the temperature. The thermal conductive body 210 may have an arc shape that corresponds to the circular shape of the substrate holder 100. For example, the curvature of the arch shape of the thermal conductive body 210 may match the curvature of an outside edge of the substrate holder 100. The thermal conductive body 210 may surround at least a portion of the substrate holder 100 along a circumference of the circular shape of the substrate holder 100. The thermal conductive body 210 may be spaced apart from the circular shape of the substrate holder 100.

A sidewall of the thermal conductive body 210 may be spaced apart from a side surface of the substrate holder 100 by a predetermined distance (e.g., a first distance D1). The thermal conductive body 210 may move in a same direction as the substrate holder 100. In some embodiments, the thermal conductive body 210 moves together with the substrate holder 100 and maintains the predetermined distance, e.g., the first distance D1. For example, the first distance D1 may be 1 mm to 5 mm.

The first fluid transfer line 220 may move a fluid therein that is a lower temperature than the platen 20. The first fluid transfer line 220 may extend along a lower surface of the thermal conductive body 210. Since the first fluid transfer line 220 is provided adjacent to the lower surface of the thermal conductive body 210, the first fluid transfer line 220 may absorb heat that is generated from the platen 20 through the thermal conductive body 210. The first fluid transfer line 220 may absorb the heat from the thermal conductive body 210 through a cooling fluid, for example, water. However, embodiments are not necessarily limited to water as the cooling fluid, and another fluid such as a refrigerant may be used.

The second fluid transfer line 230 may move a fluid therein that is a higher temperature than the platen 20. The second fluid transfer line 230 may extend along the lower surface of the thermal conductive body 210. Since the second fluid transfer line 230 is provided adjacent to the lower surface of the thermal conductive body 210, the second fluid transfer line 230 may supply heat onto the platen 20 through the thermal conductive body 210. The second fluid transfer line 230 may supply the heat to the thermal conductive body 210 through a heating fluid, for example, water. However, embodiments are not necessarily limited to water as the heating fluid, and another fluid such as a refrigerant may be used. Hereinafter, the cooling and heating fluids will be referred to as water as an example.

The first and second fluid transfer lines 220 and 230 may receive the cooling water and the heating water from a fluid supply. The cooling water and the heating water supplied from the fluid supply may be used to control the temperature of the platen 20, and the used cooling water and the used heating water may be recovered from the first and second fluid transfer lines 220 and 230.

In example embodiments, the thermal conductive body 210 may have a plurality of grooves 212 capable of distributing the slurry 32 on the platen 20. The plurality of grooves 212 may be provided on the lower surface of the thermal conductive body 210.

The plurality of grooves 212 may extend along a radial direction of the arc shape of the thermal conductive body 210. Grooves of the plurality of grooves 212 may be arranged along a circumference of the arc shape of the thermal conductive body 210. The plurality of grooves 212 may distribute the slurry 32 on the platen 20 based on movement of the substrate holder 100. Since the plurality of grooves 212 extend in the radial direction, when the substrate holder 100 and the thermal conductive body 210 move in a horizontal direction, the plurality of grooves may distribute the slurry 32 over a wide area through the radial direction.

As illustrated in FIG. 4, the thermal conductive body 210 may have a central portion CP and first and second end portions EP1 and EP2 provided on both sides of the central portion CP. The first and second end portions EP1 and EP2 may be adjacent to each side of the central portion CP, respectively. For example, the first end portion EP1 may extend from one side of the central portion CP along the circumference of the thermal conductive body 210, and the second end portion EP2 may extend from the opposite side of the central portion CP along the circumference of the thermal conductive body 210. In one embodiment, the plurality of grooves 212 are provided along the first and second end portions EP1 and EP2 of the arc shape. The thermal conductive body 210 may distribute the slurry 32 on the platen through the plurality of grooves 212 provided at the first and second end portions EP1 and EP2. In some embodiments, the thermal conductive body 210 may increase a contact area or a contact pressure with the platen 20 to increase thermal conductivity through the central portion CP that does not include the plurality of grooves 212, as shown in the embodiment illustrated by FIG. 4.

As illustrated in FIG. 5, the plurality of grooves 212 may be provided along the central portion CP of the arc shape. The thermal conductive body 210 may distribute the slurry 32 on the platen through the grooves 212 provided in the central portion CP. In some embodiments, the thermal conductive body 210 may increase the contact area or a contact pressure with the platen 20 to increase the thermal conductivity through the first and second end portions EP1 and EP2 that do not include the plurality of grooves 212, as shown in the embodiment illustrated by FIG. 5.

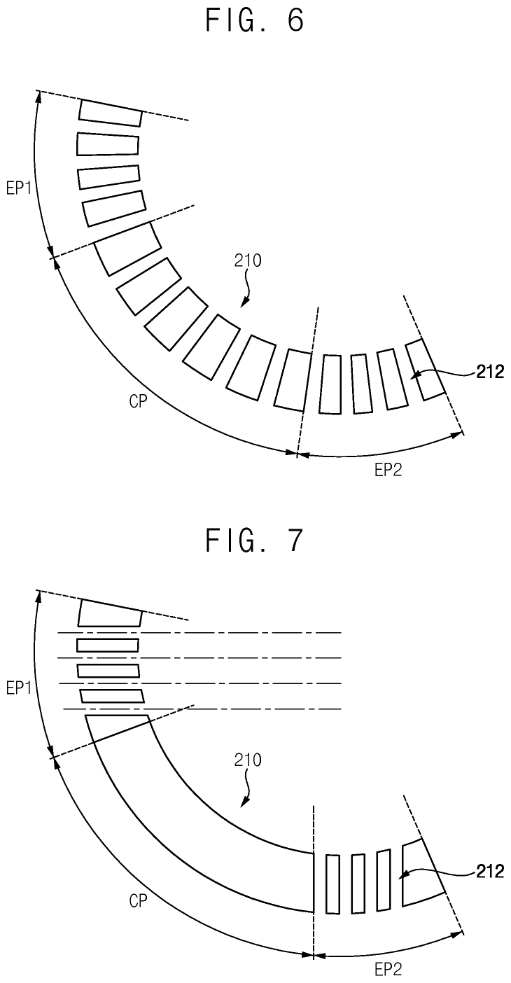

As illustrated in FIG. 6, the plurality of grooves 212 may be provided along the central portion CP and along first and second end portions EP1 and EP2 of the arc shape. The thermal conductive body 210 may distribute the slurry 32 on the platen through the plurality of grooves 212 provided in the central portion CP and the first and second end portions EP1 and EP2. The placement of the plurality of grooves 212 provided on the central portion CP and the first and second end portions EP1 and EP2 may increase dispersion efficiency of the slurry 32.

As illustrated in FIG. 7, the plurality of grooves 212 may extend parallel to each other on the lower surface of the thermal conductive body 210. The plurality of grooves 212 may distribute the slurry 32 on the platen 20 in the movement process of the substrate holder 100. Since the plurality of grooves 212 extend parallel to each other, when the substrate holder 100 and the thermal conductive body 210 rotate, the plurality of grooves 212 may distribute the slurry 32 over a wide area. In some cases, the plurality of grooves 212 include multiple sets of grooves spaced apart from each other, and each the grooves within each set of grooves extend parallel to each other.

In example embodiments, the cleaning component 300 may move on the platen 20 together with the substrate holder 100. The cleaning component 300 may supply a cleaning solution to the substrate holder 100, and the cleaning component 300 may remove foreign substances formed in the substrate holder 100 through the cleaning solution.

The cleaning component 300 may be mechanically connected to the substrate holder 100 and the temperature controller 200. For example, the cleaning component 300 may include one or more connecting members that mechanically connect the cleaning component 300 to the temperature controller 200. The cleaning component 300 may share an axis of rotation with substrate holder 100. The cleaning component 300 may move on the platen 20 together with the substrate holder 100 and the temperature controller 200. Since the temperature controller 200 surrounds the circular shape of the substrate holder 100 through the arc shape, the cleaning component 300 may be simultaneously connected to the substrate holder 100 and the temperature controller 200.

The cleaning component 300 may simultaneously supply the cleaning solution to the substrate holder 100 and the temperature controller 200, and the substrate holder 100 and the temperature controller 200 may be washed simultaneously. The cleaning component 300 may simultaneously clean an inside of the substrate holder 100 and a surface of the thermal conductive body 210.

For example, the cleaning component 300 may spray the cleaning solution to an inner wall 102 of the substrate holder 100 in which the semiconductor substrate W is accommodated. The cleaning component 300 may spray the cleaning solution to an outer wall 202 of the temperature controller 200. The cleaning component 300 may simultaneously spray the cleaning solution to the inner wall 102 of the substrate holder 100 and the outer wall 202 of the temperature controller 200.

The cleaning solution may include various fluids capable of removing substances that remain inside the substrate holder 100 and outside the thermal conductive body 210, e.g., during or after a polishing process. For example, the cleaning solution may include deionized water (DIW). The cleaning solution may include ammonia (NH₃), sulfuric acid (H₂SO₄), ozone (O₃), hydrofluoric acid (HF), hydrogen peroxide (H₂O₂), and the like. The cleaning solution may be sprayed on the inside of the substrate holder 100 and the outside of the thermal conductive body 210 in a liquid state or a gaseous (e.g., steam) state.

In example embodiments, the substrate polishing apparatus 10 may further include a pad conditioner 40. The pad conditioner 40 may distribute the slurry 32 on the platen 20. The pad conditioner 40 may restore the surface roughness of the platen 20. For example, in some cases, the platen 20 may lose roughness over time as material from processed wafers (and other sources) fills in microscopic valleys in the platen 20. In some cases, this reduces the polishing power of the platen 20. The pad conditioner 40 may polish the surface of the platen using a diamond to restore the surface roughness of the platen 20. The pad conditioner 40 may prevent residue remaining on the platen 20 from interfering with a supply of the slurry 32. In at least one embodiment, the pad conditioner 40 applies a solution other than the slurry 32 on the platen 20.

As described above, the temperature controller 200 of the substrate polishing apparatus 10 may directly contact the platen 20 to control the temperature on the platen 20. Since the temperature controller 200 is in direct contact with the platen 20, the substrate polishing apparatus 10 may prevent dilution of the slurry 32. Since the temperature controller 200 does not spray fluid onto the platen 20, waste water may be reduced.

Since the thermal conductive body 210 of the temperature controller 200 has an arc shape that surrounds the circular shape of the substrate holder 100, the temperature in a peripheral area of the substrate holder 100 may be effectively controlled. In some embodiments, since the temperature controller 200 moves in conjunction with the substrate holder 100 on the platen 20, the temperature of the platen 20 may be efficiently controlled. Since the temperature controller 200 and the substrate holder 100 each have structures whose shapes correspond to each other, the cleaning component 300 may efficiently simultaneously clean the temperature controller 200 and the substrate holder 100, as the cleaning solution from cleaning component 300 is efficiently delivered to both the temperature controller 200 and the substrate holder 100. Further, since embodiments of the thermal conductive body 210 of the temperature controller 200 include the plurality of grooves 212 on the lower surface the thermal conductive body 210 may efficiently distribute the slurry 32 on the platen 20 through the plurality of grooves 212.

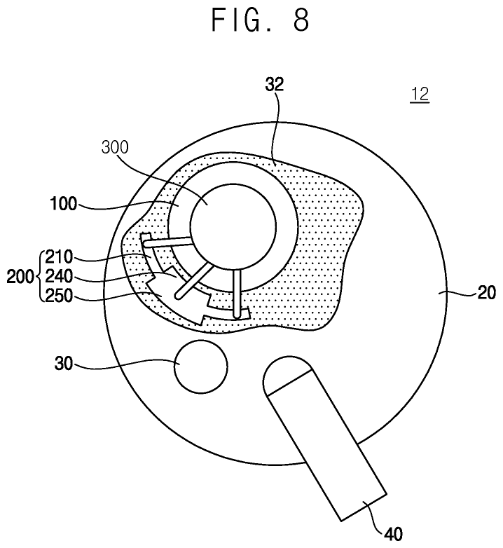

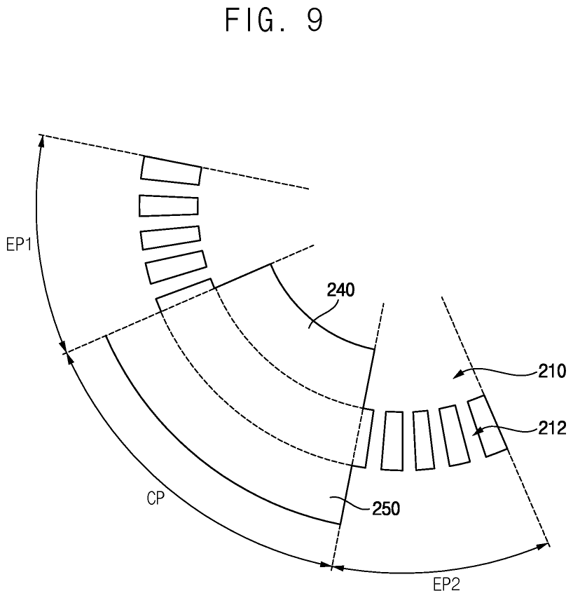

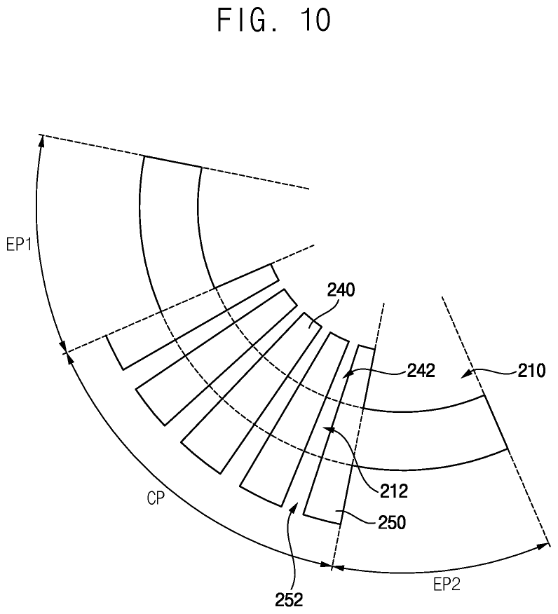

FIG. 8 is a plan view that illustrates a substrate polishing apparatus including a temperature controller that has a thermal conductive structure in accordance with example embodiments. FIGS. 9 to 11 are views that illustrate a thermal conductive body having a plurality of grooves. The substrate polishing apparatus may be similar to the substrate polishing apparatus described with reference to FIGS. 1 to 7 except for a configuration of a thermal conductive structure. The same or similar components may be denoted by the same reference numerals, and to the extent that descriptions of components are omitted, it will be appreciated that description of the same or similar components may be found elsewhere throughout the specification.

Referring to FIGS. 1 to 11, a substrate polishing device 12 may include a platen 20 configured to support a semiconductor substrate W, the slurry supply 30 configured to supply slurry 32 between the semiconductor substrate W and the platen 20, a substrate holder 100 configured to hold and fix the semiconductor substrate W on the platen 20 such that the semiconductor substrate W can be attached or detached from the platen 20, and a temperature controller 200 configured to control the temperature of the platen 20.

In example embodiments, the temperature controller 200 may include the thermal conductive body 210 which contacts platen 20 and is configured to control the temperature of the platen 20, a first thermal conductive structure 240 provided on an inner surface of the thermal conductive body 210, a second thermal conductive structure 250 provided on an outer surface of the thermal conductive body 210, a first fluid transfer line 220 (shown in, e.g., FIG. 3) configured to absorb the heat from the thermal conductive body 210 and the first and second thermal conductive structures 240 and 250, and a second fluid transfer line 230 (shown in, e.g., FIG. 3) configured to supply the heat to the thermal conductive body 210 and the first and second thermal conductive structures 240 and 250.

The thermal conductive body 210 may have a central portion CP and first and second end portions EP1 and EP2 extending from the central portion CP. The first thermal conductive structure 240 may be provided on the inner surface of the thermal conductive body 210 on the central portion CP. For example, the first thermal conductive structure 240 may be disposed proximal to the substrate holder 100 with respect to the second thermal conductive structure 250. The second thermal conductive structure 250 may be provided on the outer surface of the thermal conductive body 210 on the central portion CP. For example, the second thermal conductive structure 250 may be disposed distal to the substrate holder 100 with respect to the first thermal conductive structure 240.

The first and second thermal conductive structures 240 and 250 may contact the surface of the platen 20 to control the temperature. The first and second thermal conductive structures 240 and 250 may have an arc shape corresponding to the circular shape of the substrate holder 100. For example, the arc shape of the first and second thermal conductive structures 240 and 250 may have a curvature that conforms to the circular shape of the substrate holder 100. The first and second thermal conductive structures 240 and 250 may move in the same direction as the substrate holder 100. For example, the first and second thermal conductive structures 240 and 250 follow a rotational direction of the substrate holder 100. The first and second thermal conductive structures 240 and 250 may have increased the contact area between the platen 20 and the thermal conductive body 210 due to their arc shape.

The sidewall of the first thermal conductive structure 240 may be spaced apart from the side surface of the substrate holder 100 by the predetermined distance (e.g., the first distance D1). The first thermal conductive structure 240 may move together with the substrate holder 100 to maintain the predetermined distance. For example, the first distance D1 may be between 1 mm to 5 mm.

The first fluid transfer line 220 may move the cooling water therein. As described previously, first fluid transfer line 220 may move another fluid such as a refrigerant to cool the platen 20, though this fluid may be referred to as ‘cooling water’ for simplicity. The first fluid transfer line 220 may extend along lower surfaces of the first and second thermal conductive structures 240 and 250. Since the first fluid transfer line 220 is provided adjacent to the lower surfaces of the first and second thermal conductive structures 240 and 250, the first fluid transfer line 220 may absorb the heat generated from the platen 20 through the first and second thermal conductive structures 240 and 250. The first fluid transfer line 220 may absorb the heat from the first and second thermal conductive structures 240 and 250 through the cooling water.

The second fluid transfer line 230 may move the heating water therein. As described previously, second fluid transfer line 230 may move another fluid such as a refrigerant to heat the platen 20, though this fluid may be referred to as ‘heating water’ for simplicity. The second fluid transfer line 230 may extend along the lower surfaces of the first and second thermal conductive structures 240 and 250. Since the second fluid transfer line 230 is provided adjacent to the lower surfaces of the first and second thermal conductive structures 240 and 250, the second fluid transfer line 230 may supply the heat onto the platen 20 through the first and second thermal conductive structures 240 and 250. The second fluid transfer line 230 may supply the heat to the first and second thermal conductive structures 240 and 250 through the heating water.

In example embodiments, each of the first and second thermal conductive structures 240 and 250 may include a plurality of second grooves 242 and 252 configured to distributing the slurry 32 on the platen 20. The plurality of second grooves 242 and 252 may be provided on the lower surfaces of the first and second thermal conductive structures 240 and 250.

The plurality of second grooves 242 and 252 may extend along a radial direction of the arc shape of the first and second thermal conductive structures 240 and 250. In some embodiments, the plurality of second grooves 242 and 252 are arranged along the arc shape of the first and second thermal conductive structures 240 and 250. The plurality of second grooves 242 and 252 may distribute the slurry 32 on the platen 20 based on the movement of the substrate holder 100. Since the plurality of second grooves 242 and 252 extend in the radial direction, when the substrate holder 100 and the first and second thermal conductive structures 240 and 250 move in a horizontal direction (e.g., one or more directions parallel to an upper surface of the platen 20), the plurality of second grooves 242 and 252 may distribute the slurry 32 over a wide area in the radial direction.

As illustrated in FIG. 9, the plurality of second grooves 242 and 252 may be provided along the first and second end portions EP1 and EP2 of the thermal conductive body 210, respectively. The thermal conductive body 210 may distribute the slurry 32 on the platen through the plurality of second grooves 242 and 252. The thermal conductive body 210 may increase the contact area or contact pressure with the platen 20 to increase the thermal conductivity through the central portion CP where the first and second thermal conductive structures 240 and 250 are provided.

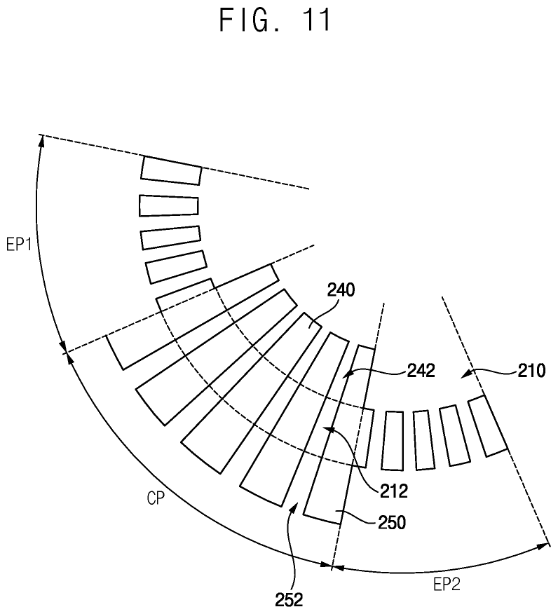

As illustrated in FIG. 10, the plurality of first grooves 212 may be provided along the central portion CP of the thermal conductive body 210. The plurality of second grooves 242 and 252 may be provided along the first and second thermal conductive structures 240 and 250. The grooves 212, 242, and 252 may be connected to each other. For example, each groove of the grooves 212, 242, and 252 may belong to the same groove structure. The thermal conductive body 210 may distribute the slurry 32 on the platen through the plurality of first and second grooves 242 and 252 that are provided on the thermal conductive body 210 and the first and second thermal conductive structures 240 and 250. The thermal conductive body 210 may increase the contact area or contact pressure with the platen 20 to increase the thermal conductivity through the first and second end portions EP1 and EP2 that are not provided with the plurality of first and second grooves 212, 242, and 252.

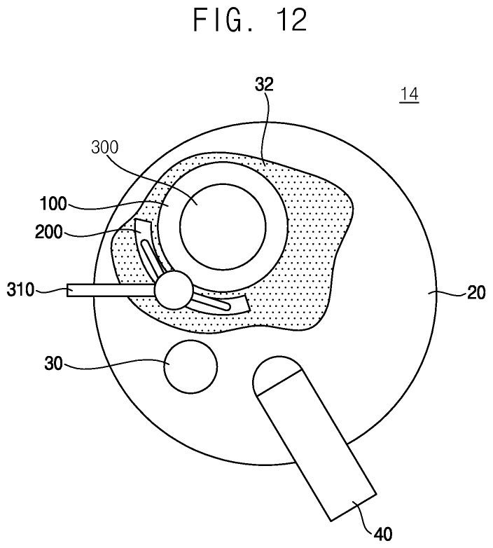

As illustrated in FIG. 11, the plurality of first grooves 212 may be provided along the central portion CP and first and second end portions EP1 and EP2 of the arc shape. The plurality of second grooves 242 and 252 may be provided along the first and second thermal conductive structures 240 and 250. The plurality of first and second grooves 212, 242, and 252 may be connected to each other. The thermal conductive body 210 may distribute the slurry 32 on the platen through the plurality of first grooves 212 provided on the central portion CP and on the first and second end portions EP1 and EP2. The plurality of first grooves 212 provided on the central portion CP and the first and second end portions EP1 and EP2 may increase the dispersion efficiency of the slurry 32.

FIG. 12 is a plan view that illustrates a substrate polishing apparatus including a temperature controller that is controlled independently of a substrate holder in accordance with example embodiments. The substrate polishing apparatus may be substantially the same as or similar to the substrate polishing apparatus described with reference to FIGS. 1 to 11 except for a configuration of a cleaning component. The same or similar components may be denoted by the same reference numerals, and to the extent that descriptions of components are omitted, it will be appreciated that description of the same or similar components may be found elsewhere throughout the specification.

Referring to FIGS. 1 to 12, a substrate polishing apparatus 14 may include the platen 20 configured to support the semiconductor substrate W, the slurry supply 30 configured to supply the slurry between the semiconductor substrate W and the platen 20, the substrate holder 100 configured to hold and fix the semiconductor substrate W on the platen 20 such that the semiconductor substrate W can be attached or detached from the platen 20, and the temperature controller 200 configured to control the temperature of the platen 20. The substrate polishing apparatus 14 may further include a first cleaning component 300 configured to clean the substrate holder 100, and a second cleaning component 310 configured to clean the temperature controller 200.

In example embodiments, the first cleaning component 300 may move on the platen 20 together with the substrate holder 100. For example, the first cleaning component 300 may follow a rotational movement of the substrate holder 100. The first cleaning component 300 may supply a cleaning solution to the substrate holder 100, and the first cleaning component 300 may remove the foreign substances formed in the substrate holder 100 through the cleaning solution.

The second cleaning component 310 may clean the temperature controller 200. The second cleaning component 310 may move on the platen 20 together with the temperature controller 200. For example, the second cleaning component 310 may follow a rotational movement of the temperature controller 200. The second cleaning component 310 may supply the cleaning solution to the temperature controller 200, and the second cleaning component 310 may remove foreign substances formed in the temperature controller 200 through the cleaning solution.

Since the first and second cleaning components 300 and 310 supply the cleaning solution to the substrate holder 100 and the temperature controller 200, respectively, the substrate holder 100 and the temperature controller 200 may move independently on the platen 20. The first and second cleaning components 300 and 310 may independently supply the cleaning solution to the substrate holder 100 and the temperature controller 200, and the first and second cleaning components 300 and 310 may independently clean the substrate holder 100 and the temperature controller 200.

The thermal conductive body 210 of the temperature controller 200 may be spaced apart from the substrate holder 100 by a predetermined distance (e.g., a second distance). The thermal conductive body 210 may move independently from a moving direction of the substrate holder 100. The thermal conductive body 210 may move outside the predetermined distance (the second distance) from the substrate holder 100. For example, the second distance may be between 5 mm to 10 mm.

Accordingly, embodiments of the present disclosure include a substrate polishing apparatus configured to control a temperature of a platen during a polishing process. The substrate polishing apparatus includes a temperature controller that directly contacts the platen, and that includes inner lines that supply the temperature controller with cooling and heating fluids. Because the cooling and heating fluids are confined to the temperature controller and not released to the platen, the fluids do not dilute or otherwise interfere with polishing slurry. Furthermore, embodiments include a cleaning component configured to apply a cleaning solution to a substrate holder and to the temperature controller. In some cases, since the temperature controller includes an arc shape that corresponds to the circular shape of the substrate holder, both the temperature controller and the substrate controller may be effectively cleaned by the cleaning component, preventing solidification and contamination from the polishing slurry and increasing reliability of the system.

The foregoing describes example embodiments of the disclosure and is not to be construed as limiting thereof. Although some embodiments have been described, those skilled in the art will readily appreciate that many modifications are possible to the embodiments without materially departing from the novel teachings and advantages of the present invention. Accordingly, all such modifications are intended to be included within the scope of the embodiments described in the appended claims.

What is claimed is:

1. A substrate polishing apparatus, comprising:
a platen including a polishing surface;
a slurry supply configured to supply slurry between a semiconductor substrate and the platen;
a substrate holder configured to hold a semiconductor substrate in contact with the platen such that the semiconductor substrate contacts the polishing surface of the platen, the substrate holder having a circular shape;
a temperature controller configured to control a temperature of the platen by directly contacting the platen, the temperature controller having a thermal conductive body including an arc shape, wherein the thermal conductive body is spaced apart from the substrate holder in a horizontal direction parallel to the polishing surface of the platen and surrounds at least a portion of the substrate holder in a plan view; and
a cleaning component configured to supply a cleaning solution to the substrate holder and to the temperature controller.

2. The substrate polishing apparatus of claim 1, wherein the temperature controller includes:
a first fluid transfer line through which cooling fluid moves along a lower surface of the thermal conductive body; and
a second fluid transfer line through which heating fluid moves along the lower surface of the thermal conductive body.

3. The substrate polishing apparatus of claim 1, wherein the thermal conductive body has a plurality of grooves disposed on a lower surface of the thermal conductive body for distributing the slurry on the platen.

4. The substrate polishing apparatus of claim 3, wherein each of the plurality of grooves extends along a radial direction of the arc shape.

5. The substrate polishing apparatus of claim 3, wherein grooves of the plurality of grooves extend parallel to each other.

6. The substrate polishing apparatus of claim 3, wherein the arc shape comprises a central portion, a first end portion disposed on one side of the central portion, and a second end portion disposed on an opposite side of the central portion, and wherein the plurality of grooves is provided along the first and second end portions of the arc shape.

7. The substrate polishing apparatus of claim 1, wherein the temperature controller further includes,
a first thermal conductive structure provided on an inner surface of the thermal conductive body proximate to the substrate holder; and
a second thermal conductive structure provided on an outer surface of the thermal conductive body distal to the substrate holder.

8. The substrate polishing apparatus of claim 7, wherein each of the first and second thermal conductive structures has a plurality of second grooves disposed on a lower surface thereof for distributing the slurry on the platen.

9. The substrate polishing apparatus of claim 1, wherein the cleaning component simultaneously sprays the cleaning solution to an inner wall of the substrate holder in which the semiconductor substrate is accommodated and to an outer wall of the temperature controller.

10. The substrate polishing apparatus of claim 1, wherein the temperature controller is held at a predetermined distance from the substrate holder, and
wherein the predetermined distance is between 1 mm to 5 mm.

11. A substrate polishing apparatus, comprising:
a platen including an upper surface configured to polish a semiconductor substrate;
a slurry supply configured to supply slurry between the semiconductor substrate and the platen;
a substrate holder configured to hold the semiconductor substrate in contact with the platen such that the semiconductor substrate contacts the upper surface of the platen, the substrate holder having a circular shape;
a temperature controller configured to control a temperature of the platen by directly contacting the platen, the temperature controller having a thermal conductive body including an arc shape with a curvature that matches a curvature of the circular shape of the substrate holder, the thermal conductive body spaced apart from the substrate holder in a plan view and surrounding at least a portion of the substrate holder, wherein the thermal conductive body includes a plurality of grooves on a lower surface thereof, and wherein the temperature controller is configured to be adjustable to a predetermined distance from the substrate holder; and
a cleaning component configured to supply a cleaning solution to the substrate holder and to the temperature controller.

12. The substrate polishing apparatus of claim 11, wherein the temperature controller includes,
a first fluid transfer line through which a cooling fluid moves along the lower surface of the thermal conductive body; and
a second fluid transfer line through which a heating fluid moves along the lower surface of the thermal conductive body.

13. The substrate polishing apparatus of claim 11, wherein each of the plurality of grooves extend along a radial direction of the arc shape.

14. The substrate polishing apparatus of claim 11, wherein grooves of the plurality of grooves extend parallel to each other.

15. The substrate polishing apparatus of claim 11, wherein the arc shape of the thermal conductive body includes a central portion, a first end portion disposed on one side of the central portion, and a second end portion disposed on an opposite side of the end portion, and wherein the plurality of grooves are provided along the first and second end portions on lower surfaces thereof, and wherein a smooth surface is provided along the central portion on a lower surface thereof.

16. The substrate polishing apparatus of claim 11, wherein the temperature controller further includes,
a first thermal conductive structure provided on an inner surface of the thermal conductive body proximate to the substrate holder; and
a second thermal conductive structure provided on an outer surface of the thermal conductive body distal to the substrate holder.

17. The substrate polishing apparatus of claim 16, wherein each of the first and second thermal conductive structures has a plurality of second grooves on a lower surface thereof for distributing the slurry on the platen.

18. The substrate polishing apparatus of claim 11, wherein the cleaning component simultaneously sprays the cleaning solution to an inner wall of the substrate holder in which the semiconductor substrate is accommodated and to an outer wall of the temperature controller.

19. The substrate polishing apparatus of claim 11, wherein the predetermined distance is between 1 mm to 5 mm.

20. A substrate polishing apparatus, comprising:
a platen including an upper surface configured to polish a semiconductor substrate;
a slurry supply configured to supply slurry between the semiconductor substrate and the platen;
a substrate holder configured to hold the semiconductor substrate to bring the semiconductor substrate into contact with the upper surface the platen, the substrate holder having a circular shape;
a temperature controller configured to control a temperature of the platen by directly contacting the platen and providing thermal transfer between the temperature controller and the platen, wherein the temperature controller is adjustable to be set to a fixed predetermined distance from the substrate holder; and
a cleaning component configured to supply a cleaning solution to the substrate holder and to the temperature controller,
wherein the temperature controller includes:
a thermal conductive body an arc shape that surrounds at least a portion of the substrate holder in a plan view and is spaced apart from the substrate holder in the plan view, the thermal conductive body having a plurality of grooves on a lower surface;
a first thermal conductive structure provided on an inner surface of the thermal conductive body proximate to the substrate holder;
a second thermal conductive structure provided on an outer surface of the thermal conductive body distal to the substrate holder;
a first fluid transfer line configured to move cooling fluid along the lower surface of the thermal conductive body; and
a second fluid transfer line configured to heating fluid along the lower surface of the thermal conductive body.
